(19) United States
(12) Patent Application Publication
(10) Pub. No.: US 2025/0020486 A1
(43) Pub. Date: Jan. 16, 2025

(54) THREE AXIS MIRROR POSITION SENSING

(71) Applicant: Gentex Corporation, Zeeland, MI (US)

(72) Inventor: Robert R. Turnbull, Holland, MI (US)

(21) Appl. No.: 18/767,298

(22) Filed: Jul. 9, 2024

Related U.S. Application Data
(60) Provisional application No. 63/526,072, filed on Jul. 11, 2023.

(51) Int. Cl. G01D 5/14; B60R 1/04; B60R 1/12; G01R 33/02

(52) U.S. Cl. CPC G01D 5/14; B60R 1/12; B60R 1/04; B60R 2001/1223; G01R 33/0206

(57) ABSTRACT

A rearview assembly includes a mount having a first end and a second end that includes a first joint portion and a main unit including a planar front face secured to a housing. The housing has a second joint portion disposed opposite the planar front face. The socket rotatably receives the ball joint portion such that the main unit is articulable on the mount along three perpendicular axes. The assembly further includes an asymmetrical magnetic unit secured to the first joint portion. a sensor mounted in the housing of the main unit and positioned in proximity to the asymmetrical magnet unit, and a processor in communication with the sensor to receive magnetic field information from the sensor and to determine a position of the main unit in relation to the mount based on the magnetic field information.

### CROSS-REFERENCE TO RELATED APPLICATION

This application claims priority to and the benefit under 35 U.S.C. § 119(e) of U.S. Provisional Application No. 63/526,072, filed on Jul. 11, 2023, entitled “THREE AXIS MIRROR POSITION SENSING,” the disclosure of which is hereby incorporated herein by reference in its entirety.

### BACKGROUND

The present disclosure relates generally to a vehicle rearview assembly and more particularly, relates to an assembly with a sensor configured to determine the axis orientation information of a main unit of the assembly relative to a mount.

Various features have been introduced to different types of vehicular rearview assemblies that can be augmented by the capability to determine the location and orientation, or pose, of a body of the rearview with respect to a base and/or the vehicle interior. Permanent magnets and magnetic sensors have been introduced as solutions in the past. Such solutions, however, are limited to magnets or sensors in a ball of a single ball-socket joint and magnets or three-axis magnetometers on the electronic board of a mirror, which may not operate with multi-jointed mounts, may have accuracy limitations, and has the disadvantage of not being able to turn off the magnetic field to measure and account for background magnetic disturbances.

### SUMMARY

According to one aspect of the present disclosure, a rearview assembly includes a mount having a first end and a second end that includes a first joint portion and a main unit including a planar front face secured to a housing. The housing has a second joint portion disposed opposite the planar front face. The socket rotatably receives the ball joint portion such that the main unit is articulable on the mount along three perpendicular axes. The assembly further includes an asymmetrical magnetic unit secured to the first joint portion. a sensor mounted in the housing of the main unit and positioned in proximity to the asymmetrical magnet unit, and a processor in communication with the sensor to receive magnetic field information from the sensor and to determine a position of the main unit in relation to the mount based on the magnetic field information.

According to another aspect of the disclosure, a rearview assembly includes a mount having a first end and a second end that includes a first joint portion and a main unit that has a planar front face secured to a housing. The housing has a second joint portion disposed opposite the planar front face. The second joint portion rotatably receives the first joint portion such that the main unit is articulable on the mount along three perpendicular axes. The assembly further includes an asymmetrical magnetic unit secured within one of the mount or the main unit, a sensor mounted in the other of the main unit or the mount and positioned in proximity to the asymmetrical magnet unit, and a processor in communication with the sensor to receive magnetic field information from the sensor and to determine a position of the main unit in relation to the mount based on the magnetic field information.

According to another aspect of the disclosure, a rearview assembly includes a mount having a first end and a second end that has a ball joint portion and a main unit including a planar front face secured to a housing. The housing has a socket disposed on an interior of the housing of the main unit adjacent an aperture through the housing disposed opposite the planar front face. The socket rotatably receives the ball joint portion such that the main unit is articulable on the mount along three perpendicular axes. The assembly further includes an asymmetrical magnetic unit including a magnet received in the cavity of the ball joint portion and a pole piece coupled with the magnet and positioned outside the cavity, a sensor mounted in the housing of the main unit and positioned in proximity to the asymmetrical magnet unit, and a processor in communication with the sensor to receive magnetic field information from the sensor and to determine a position of the main unit in relation to the mount based on the magnetic field information.

These and other features, advantages, and objects of the present device will be further understood and appreciated by those skilled in the art upon studying the following specification, claims, and appended drawings.

### BRIEF DESCRIPTION OF THE DRAWINGS

The present invention will become more fully understood from the detailed description and the accompanying drawings, wherein:

FIG. 1 is a perspective view of a rearview assembly according to an aspect of the disclosure with a main unit thereof in a first position relative to a mount;

FIG. 2 is a perspective view of the rearview assembly with the main unit in a second position relative to the mount;

FIG. 3 is a perspective view of the rearview assembly with the main unit in a third position relative to the mount;

FIG. 4 is a front perspective exploded view of the rearview assembly;

FIG. 5 is a rear perspective exploded view of the rearview assembly;

FIG. 6 is a front plan view of internal components of the rearview assembly in with the main unit thereof in the first position relative to the mount;

FIG. 7 is a front plan view of the internal components of the rearview assembly in with the main unit thereof in the second position relative to the mount; and

FIG. 8 is a front plan view of the internal components of the rearview assembly in with the main unit thereof in the second position relative to the mount.

### DETAILED DESCRIPTION OF EMBODIMENTS

The present illustrated embodiments reside primarily in combinations of method steps and apparatus components related to an electronic device housing portion. Accordingly, the apparatus components and method steps have been represented, where appropriate, by conventional symbols in the drawings, showing only those specific details that are pertinent to understanding the embodiments of the present disclosure so as not to obscure the disclosure with details that will be readily apparent to those of ordinary skill in the art having the benefit of the description herein. Further, like numerals in the description and drawings represent like elements.

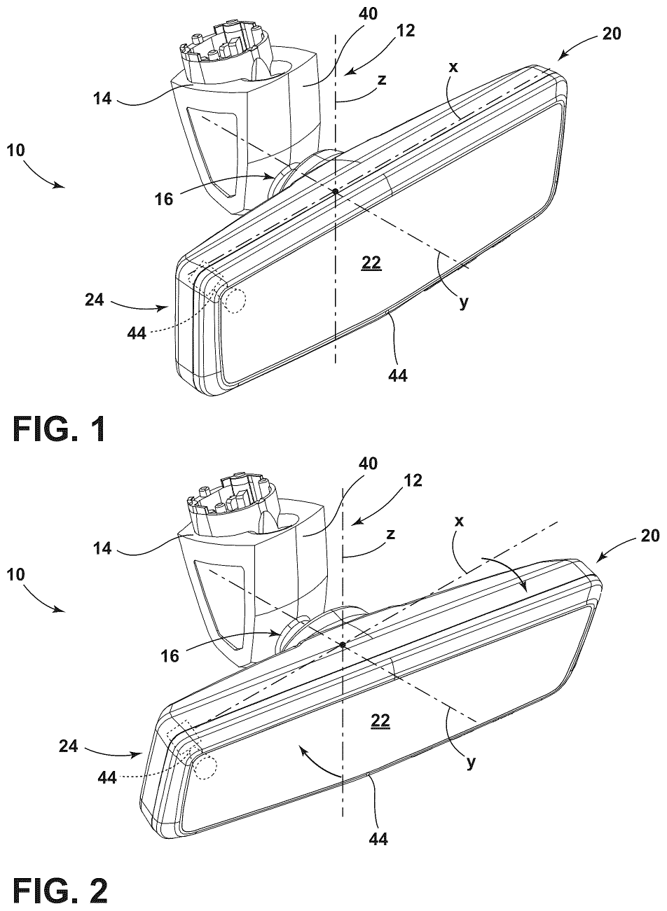

For purposes of description herein, the terms “upper,” “lower,” “right,” “left,” “rear,” “front,” “vertical,” “horizontal,” and derivatives thereof shall relate to the disclosure as oriented in FIG. 1. Unless stated otherwise, the term “front” shall refer to the surface of the element closer to an intended viewer, and the term “rear” shall refer to the surface of the element further from the intended viewer. However, it is to be understood that the disclosure may assume various alternative orientations, except where expressly specified to the contrary. It is also to be understood that the specific devices and processes illustrated in the attached drawings, and described in the following specification are simply exemplary embodiments of the inventive concepts defined in the appended claims. Hence, specific dimensions and other physical characteristics relating to the embodiments disclosed herein are not to be considered as limiting, unless the claims expressly state otherwise.

The terms “including,” “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element preceded by “comprises a . . . ” does not, without more constraints, preclude the existence of additional identical elements in the process, method, article, or apparatus that comprises the element.

Ordinal modifiers (i.e., “first”, “second”, etc.) may be used to distinguish between various structures of a disclosed article in various contexts, but such ordinals are not necessarily intended to apply to such elements outside of the particular context in which they are used and that, in various aspects different ones of the same class of elements may be identified with the same, context-specific ordinal. In such instances, other particular designations of the elements are used to clarify the overall relationship between such elements. Ordinals are not used to designate a position of the elements, nor do they exclude additional, or intervening, non-ordered elements or signify an importance or rank of the elements within a particular class.

For purposes of this disclosure, the term “coupled” (in all of its forms, couple, coupling, coupled, etc.) generally means the joining of two components (electrical or mechanical) directly or indirectly to one another. Such joining may be stationary in nature or movable in nature. Such joining may be achieved with the two components (electrical or mechanical) and any additional intermediate members being integrally formed as a single unitary body with one another or with the two components. Such joining may be permanent in nature or may be removable or releasable in nature unless otherwise stated.

For purposes of this disclosure, the terms “about”, “approximately”, or “substantially” are intended to mean that a value of a parameter is close to a stated value or position. However, minor differences may prevent the values or positions from being exactly as stated. Thus, unless otherwise noted, differences of up to ten percent (10%) for a given value are reasonable differences from the ideal goal of exactly as described. In many instances, a significant difference can be when the difference is greater than ten percent (10%), except as where would be generally understood otherwise by a person of ordinary skill in the art based on the context in which such term is used.

Referring to FIGS. 1-8, reference numeral 10 generally designates a rearview assembly. The rearview assembly 10 includes a mount 12 having a first end 14 and a second end 16 having a ball joint portion 18 defined thereon, and a main unit 20 including a planar front face 22 secured to a housing 24. The housing 24 has a socket 26 disposed on an interior 28 thereof adjacent an aperture 30 disposed opposite the planar front face 22. The socket 26 rotatably receives the ball joint portion 18 such that the main unit 20 is articulable on the mount 12 along three perpendicular axes (X, Y and Z). An asymmetrical magnetic unit 32 (FIG. 4) is secured to the ball joint portion 18 and a sensor 34 is mounted in the interior 28 of the main unit 20 and is positioned in proximity to the asymmetrical magnet unit 32. A processor 35 is in communication with the sensor 34 to receive magnetic field information from the sensor 34 and determines a position of the main unit 20 in relation to the mount 12 based on the magnetic field information.

As can be appreciated, the rearview assembly 10 described herein can be used in connection with a vehicle, particularly within the interior thereof. In particular, rearview assembly 10 can be mounted adjacent a windshield of vehicle either by attachment of the mount 12 with the windshield itself or to an additional component adjacent or mounted to the headliner in an area above a top edge of the windshield (such mounting may be made to a portion of the vehicle frame, a vehicle panel, or other support structure, for example, through one or more apertures in the headliner). The above-mentioned connection of the main unit 20 with the mount 12 by way of the receipt of the ball joint portion 18 within the socket 26 associated with the main unit 20 facilitates positioning of the planar face 22 of the main unit 20 in a desired position within the vehicle interior. In particular, this positioning is made adjustable by the ball-and-socket joint 36 defined by the attachment of the ball joint portion 18 with the socket 26. As can be appreciated, this adjustable positioning is realized by articulation of the socket 26 about the ball joint portion 18 and is limited in a range of motion about the Z axis and a similar range of motion about the X axis by the size of the aperture 30 relative to a stem 38 that connects the ball joint portion 18 to a base 40 of the mount 12. In various implementations, the respective ranges of rotational motion about each of the Z-axis and X-axis can be at least about 30° from the centered position shown in FIGS. 1 and 6, although other variations are possible. In this respect, FIG. 2 shows the main unit 20 rotated about each of the Z-axis and the X-axis by 15° from the center position of FIG. 1.

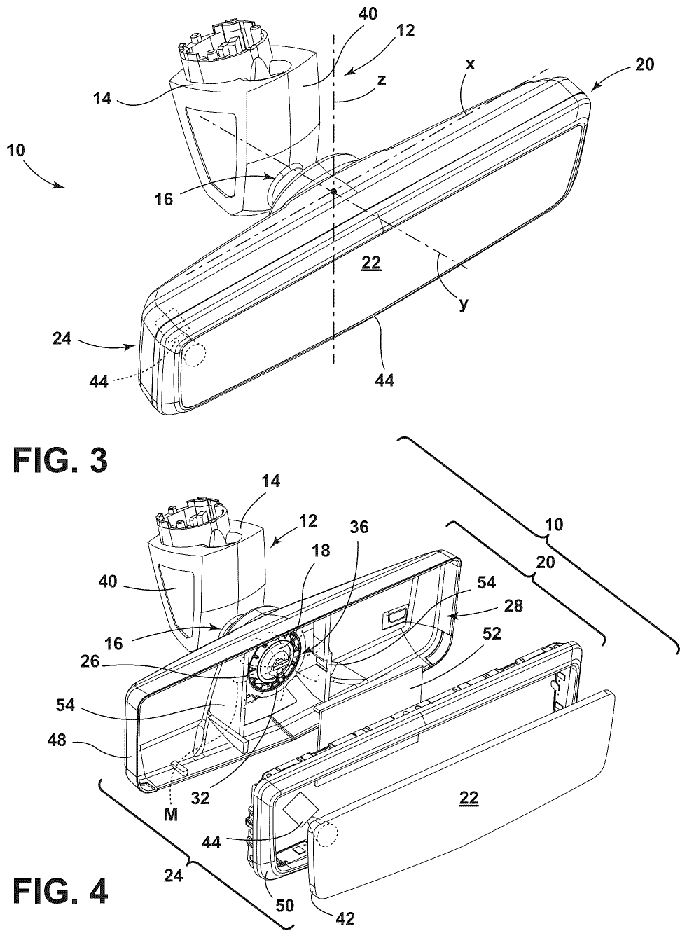

The structure of the joint 36 depicted herein can be such that the main unit 20 rotates freely on the ball joint 18 with respect to the Y-axis, although, in some aspects interference with the base 40 and/or adjacent parts of the vehicle (including, for example, the headliner) can restrict such rotation. In other aspects, additional structures within or associated with the joint 36 can restrict the Y-axis rotation of the main unit 20 to less than 360° about the ball joint portion 18 (for example, to within about 45° in either direction from the centered position of FIGS. 1 and 6) to prevent stressing or crimping of electrical connections between features within the interior 28 to the vehicle that pass through the joint 36 and the mount base 40. In this respect, FIG. 3 shows the main unit 20 rotated by about 10° on the Y-axis from the position of FIG. 2, discussed above.

In one example of the rearview assembly 10, described herein, the planar face 22 of the main unit 20 can be on a mirrored element 42 (FIG. 4) that is generally configured to present a reflected image of the view to the rear of vehicle to a driver and, accordingly, may be adjustable by movement of main unit 20 with respect to mount 12. In one embodiment, the mirrored element 42 can be in the form of an electro-optic element such that the planar face 22 is associated with a transparent element that encloses an electro-optic medium that can be made more transmissible or less transmissible by application of an electric current thereto. In such an example, an interior surface of the mirrored element 42 defines the reflective surface. In such an example, the main unit 20 may include an interior imager 44 that can be positioned within the housing 24 and configured to capture an image through a properly configured portion of the mirrored element 42. Alternatively, the imager 44 can be exposed on the housing 24 adjacent the mirrored element 42, with such imager, in one example, being useable in connection with a driver monitoring system. While both such configurations are shown together in FIGS. 1-4, it is to be understood that only one such imager 44 may be necessary.

In another example, the planar face 22 of the main unit may be defined on a display unit (that is schematically similar to the mirrored element 42 shown in the drawings for purposes of this discussion). In this respect, the rearview assembly 10 may be what may be referred to as a full-display mirror. As can be appreciated, the display unit may be capable of displaying a simulated mirror-image of the view to the rear of the associated vehicle (that may be captured by an appropriately-positioned video camera or the like) when the display is in an active state. Such an image may generally replicate that which would be available from a typical reflective mirror and can be supplemented with other information presented on the display unit. In one aspect, such an image may be responsive to the position of the main unit 20 about the mount 12, such that movement of the main unit 20 is linked with panning or rotation of the image presented on the display in the same way that movement of a mirrored surface changes the point-of-view of the reflected image. An example of such a system is discussed further in commonly-assigned U.S. Pat. No. 10,525,890 (“the '890 Patent”), the entire contents of which are incorporated by reference herein.

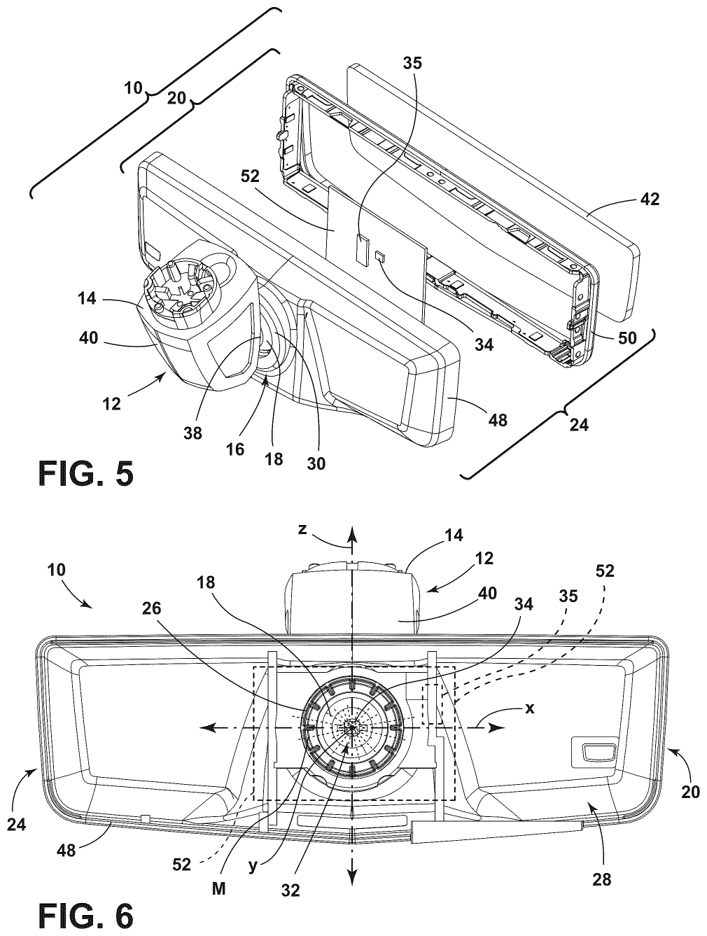

As can be seen in FIGS. 4 and 5, the socket 26 can be assembled within or integrally molded as a part of the housing 24. In the illustrated example, the housing 24 includes a front (i.e., with respect to the orientation of the rearview mirror assembly 10 within a vehicle) housing portion 48, which is shown in the form of a single-piece unit and can be made from a single piece of injection molded plastic or the like, although other materials are possible. In the depicted embodiment, socket 26 is incorporated into the structure of the rear housing 48 on an interior 28 thereof such that the socket 26 aligns with the aperture 30, which is also formed in the rear housing 48. In turn, the depicted mirrored element 42 (or, in the alternative the display unit) can be coupled to the rear housing 48 by way of a bezel 50 or other secondary housing piece that affixes to the rear housing 48 to complete and enclose the housing 24, thereby defining the interior 28 along with the mirrored element 42. In this and other examples, the housing 24 is structured so that the interior 28 is of a sufficient depth to retain internal structures of rearview assembly 10, including the joint 36 and other related structures, such as those related to the above-described electro-optic element or display substrate, the interior imager 44 and other elements known in the art or described later herein.

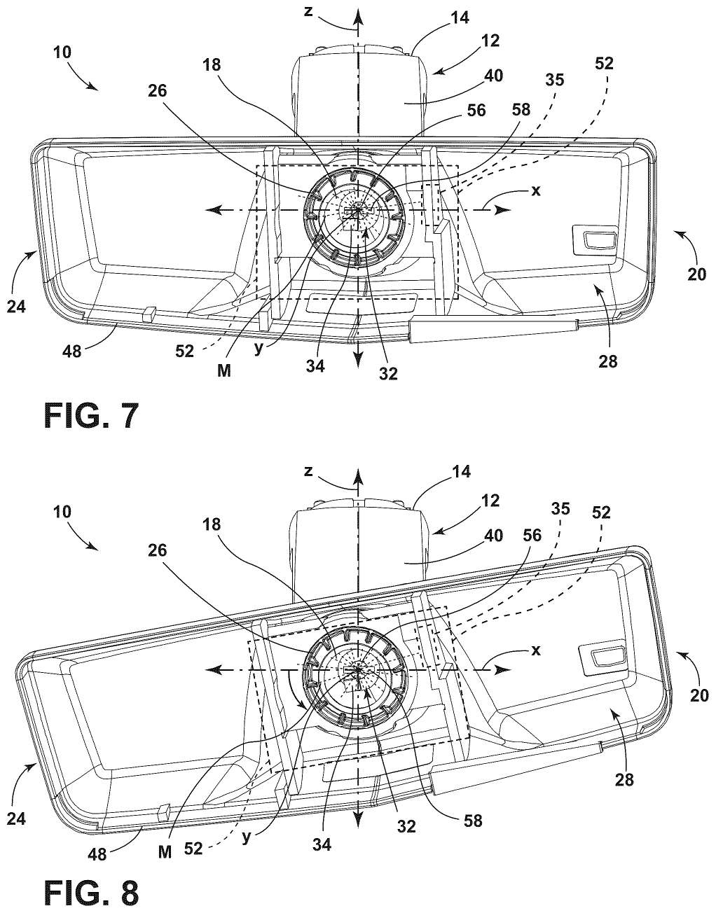

As can be appreciated, the variations of the rearview assembly 10, discussed above, in which the rearview assembly 10 incorporates at least one of a position-responsive display associated with the planar face 22 and/or an interior imager 44 for driver monitoring, the associated systems may advantageously utilize position information of the main unit 20 relative to the mount 12. As further shown in FIGS. 4 and 5, such information may be obtained using the above-mentioned sensor 34. In particular, the sensor 34 can be configured as a magnetic field sensor that can determine the location of the above-described magnetic unit 32 with respect thereto. In this manner, the sensor 34 can be mounted on a printed circuit board (“PCB”) 52 that is mounted within the interior 28 of housing 24. In one aspect, the PCB 52 can be mounted by mechanical fasteners or the like to spaced-apart ribs 54 formed with the front housing 48. As further shown, the magnetic unit 32 includes a fixed magnet 56 received within a boss formed in the ball joint portion 18. In this arrangement, the fixed magnet 56 remains stationary while the sensor 34 moves with the main unit 20 during articulation thereof about the ball joint portion 18. Accordingly, the rotation of the main unit 20 about the Z-axis and the X-axis can be determined by the processor 35 by correlating the location of the sensor 34 with respect to the fixed magnet 56 in the X-Z plane, as shown in FIG. 6, wherein alignment of the sensor 34 with the magnet in the X-Z plane indicates the depicted centered position, and in FIG. 7, wherein the displaced position in the Z-direction and the X-direction correlates with the position shown in FIGS. 2 and 7, wherein the main unit 20 is rotated on both the X-axis and the Z-axis, as described above.

Notably, the additional rotation of the main unit 20 about the Y-axis does not change the relative location of the sensor 34 with respect to the fixed magnet 56 in the X-Z plane such that additional information is needed for the processor 35 to determine the rotational positioning of the main unit 20 about the Y-axis. In this respect, magnetic field sensors of the type that can be used for the sensor 34 discussed herein can measure magnetic field characteristics that can indicate rotation and/or orientation of the sensor with respect to a magnetic field. Many fixed magnets, however, including the cylindrical fixed magnet 56 depicted herein are associated with a symmetric magnetic field (i.e., having generally even effects in the X and Z directions) such that the rotational position of the sensor 34 with respect to the fixed magnet 56 does not cause a variation in the associated magnetic field such that even an appropriately configured sensor 34 does not output any magnetic field data useable by the processor 35 in determining the rotational position about the Y-axis. In this respect, the present rearview assembly 10 incorporates a magnetic unit 32 that exhibits an asymmetrical magnetic field in the X-Z plane. In the example shown herein, the magnet unit 32 includes a pole piece 58 that is coupled with the fixed magnet 56 and is elongated so as to extend outwardly therefrom in the direction of the X-axis (a similar arrangement extending in the Z-axis or an offset axis can also achieve the same effect discussed herein). In general, a pole piece is a structure composed of material of high magnetic permeability that serves to direct the magnetic field produced by a magnet by attaching to and, in a sense, extending a pole of the magnet in the direction in which the pole piece extends. While the pole piece 58 shown herein is in the form of a bar having a generally square cross-section, other shapes and configurations are possible and may be generally understood in the art.

As shown, the inclusion of the pole piece 58 extends the magnetic field M outwardly from the fixed magnet 56 to a greater extent in the X-axis as compared to the Z-axis. In this manner, the magnetic field information measured and output by the sensor 34 to the processor 35 can include an orientation of the asymmetrical magnetic field M relative to the sensor 34. In this manner, the position of the main unit 20 in relation to the mount 12 includes a rotational position of the main unit 20 about each of the three perpendicular axes (X, Y, and Z) about which the main unit 20 is articulable on the mount 12. FIGS. 7 and 8 depict the change in orientation of the sensor 34 with respect to the magnetic field M exhibited by the magnet unit 32 including the above-described pole piece 58. In alternative arrangements, asymmetrical magnets (e.g., horseshoe magnets) or multiple magnets separated by or separately embedded into a substantially non-magnetic material (such as various dielectrics or non-magnetic metals such as aluminum or brass, for example) can be used to achieve a similar effect. By adding the pole piece 58 to the fixed magnet 56 or using an asymmetrical magnet, it is possible to calculate the additional position parameter of rotation about the Y-axis using an existing sensor 34. In one example, a “joystick” position sensor available through Melexis of Belgium, EU, can be used for the sensor 34. The position of the main unit 20 relative to the mount 12, discussed herein, can be determined with this arrangement, even if the mirror is moved when unpowered or when the vehicle is stationary.

It is further noted that other arrangements are possible in which the sensor 34 is coupled with the mount 12 and the asymmetric magnet unit 32 is coupled within the housing 24. In such an arrangement, the sensor 34 can be connected to the PCB 52 and the processor 35 by a wired connection with the PCB 52 remining in the depicted position, as mounted to the housing 48. In alternative implementations, the PCB can be positioned within the base 40 of the mount 12.

The invention disclosed herein is further summarized in the following paragraphs and is further characterized by combinations of any and all of the various aspects described therein.

According to another aspect of the present disclosure, a rearview assembly includes a mount having a first end and a second end having a ball joint portion defined thereon, and a main unit including a planar front face secured to a housing. The housing has a socket disposed on an interior thereof adjacent an aperture disposed opposite the planar front face. The socket rotatably receives the ball joint portion such that the main unit is articulable on the mount along three perpendicular axes. An asymmetrical magnetic unit is secured to the ball joint portion and a sensor is mounted in the housing of the main unit and is positioned in proximity to the asymmetrical magnet unit. A processor is in communication with the sensor to receive magnetic field information from the sensor and determines a position of the main unit in relation to the mount based on the magnetic field information.

In the rearview assembly of ¶ [0029], the asymmetrical magnetic unit can include a magnet and a pole piece coupled with the magnet.

In the rearview assembly of either of ¶¶ [0029] or [0030], the magnetic field information can include a location of a magnetic field relative to the sensor.

In the rearview assembly of any of ¶¶ [0029] to [0031], the magnetic field information can include an orientation of an asymmetrical magnetic field relative to the sensor.

In the rearview assembly of any of ¶¶ [0029] to [0032], the position of the main unit in relation to the mount includes a rotational position of the main unit about each of the three perpendicular axes about which the main unit is articulable on the mount.

In the rearview assembly of any of ¶¶ [0029] to [0033], the planar front face is defined on a mirror couple with the housing.

In the rearview assembly of ¶¶ [0029] to [0033], the planar front face is defined on a display coupled with the housing.

It will be understood by one having ordinary skill in the art that construction of the described disclosure and other components is not limited to any specific material. Other exemplary embodiments of the disclosure disclosed herein may be formed from a wide variety of materials, unless described otherwise herein.

It is also important to note that the construction and arrangement of the elements of the disclosure as shown in the exemplary embodiments is illustrative only. Although only a few embodiments of the present innovations have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter recited. For example, elements shown as integrally formed may be constructed of multiple parts or elements shown as multiple parts may be integrally formed, the operation of the interfaces may be reversed or otherwise varied, the length or width of the structures and/or members or connector or other elements of the system may be varied, the nature or number of adjustment positions provided between the elements may be varied. It should be noted that the elements and/or assemblies of the system may be constructed from any of a wide variety of materials that provide sufficient strength or durability, in any of a wide variety of colors, textures, and combinations. Accordingly, all such modifications are intended to be included within the scope of the present innovations. Other substitutions, modifications, changes, and omissions may be made in the design, operating conditions, and arrangement of the desired and other exemplary embodiments without departing from the spirit of the present innovations.

It will be understood that any described processes or steps within described processes may be combined with other disclosed processes or steps to form structures within the scope of the present disclosure. The exemplary structures and processes disclosed herein are for illustrative purposes and are not to be construed as limiting.

What is claimed is:

1. A rearview assembly comprising:
a mount having a first end and a second end, wherein the second end includes a first joint portion;
a main unit including a planar front face secured to a housing, the housing having a second joint portion disposed opposite the planar front face, the socket rotatably receiving the ball joint portion such that the main unit is articulable on the mount along three perpendicular axes;
an asymmetrical magnetic unit secured to the first joint portion;
a sensor mounted in the housing of the main unit and positioned in proximity to the asymmetrical magnet unit; and
a processor in communication with the sensor to receive magnetic field information from the sensor and to determine a position of the main unit in relation to the mount based on the magnetic field information.

2. The rearview assembly of claim 1, wherein the asymmetrical magnetic unit includes a magnet and a pole piece coupled with the magnet.

3. The rearview assembly of claim 1, wherein the asymmetrical magnetic unit includes at least two magnets separated by a dielectric material.

4. The rearview assembly of claim 1, wherein the magnetic field information includes a location of a magnetic field relative to the sensor.

5. The rearview assembly of claim 1, wherein the magnetic field information includes an orientation of an asymmetrical magnetic field relative to the sensor.

6. The rearview assembly of claim 1, wherein the position of the main unit in relation to the mount includes a rotational position of the main unit about each other three perpendicular axes about which the main unit is articulable on the mount.

7. The rearview assembly of claim 1, wherein the planar front face is defined on a mirror coupled with the housing.

8. The rearview assembly of claim 1, wherein the planar front face is defined on a display coupled with housing.

9. The rearview assembly of claim 1, wherein:
the first joint portion comprises a ball joint portion; and
the second joint portion comprises a socket disposed on an interior of the housing of the main unit adjacent an aperture through the housing.

10. The rearview assembly of claim 9, wherein the asymmetrical magnet unit is embedded within the ball joint portion.

11. The rearview assembly of claim 1, wherein the sensor is mounted on a printed circuit board secured within the housing.

12. A rearview assembly comprising:
a mount having a first end and a second end, wherein the second end includes a first joint portion;
a main unit including a planar front face secured to a housing, the housing having a second joint portion disposed opposite the planar front face, the second joint portion rotatably receiving the first joint portion such that the main unit is articulable on the mount along three perpendicular axes;
an asymmetrical magnetic unit secured within one of the mount or the main unit;
a sensor mounted in the other of the main unit or the mount and positioned in proximity to the asymmetrical magnet unit; and
a processor in communication with the sensor to receive magnetic field information from the sensor and to determine a position of the main unit in relation to the mount based on the magnetic field information.

13. The rearview assembly of claim 12, wherein the asymmetrical magnetic unit includes a magnet and a pole piece coupled with the magnet.

14. The rearview assembly of claim 12, wherein the magnetic field information includes a location of a magnetic field relative to the sensor.

15. The rearview assembly of claim 12, wherein the magnetic field information includes an orientation of an asymmetrical magnetic field relative to the sensor.

16. The rearview assembly of claim 12, wherein the position of the main unit in relation to the mount includes a rotational position of the main unit about each other three perpendicular axes about which the main unit is articulable on the mount.

17. The rearview assembly of claim 12, wherein:
the first joint portion is a socket; and
the second joint portion is a ball joint portion extending from the housing and received in the socket.

18. A rearview assembly, comprising:
a mount having a first end and a second end, wherein the second end includes a ball joint portion;
a main unit including a planar front face secured to a housing, the housing having a socket disposed on an interior of the housing of the main unit adjacent an aperture through the housing disposed opposite the planar front face, the socket rotatably receiving the ball joint portion such that the main unit is articulable on the mount along three perpendicular axes;
an asymmetrical magnetic unit including a magnet received in the cavity of the ball joint portion and a pole piece coupled with the magnet and positioned outside the cavity;
a sensor mounted in the housing of the main unit and positioned in proximity to the asymmetrical magnet unit; and
a processor in communication with the sensor to receive magnetic field information from the sensor and to determine a position of the main unit in relation to the mount based on the magnetic field information.

19. The rearview assembly of claim 18, wherein:
the magnet extends along a polar axis; and
the pole piece defines a second axis perpendicular to the polar axis.

20. The rearview assembly of claim 18, wherein the pole piece is of a magnetically permeable material.
